(19) United States
(12) Patent Application Publication
(10) Pub. No.: US 2026/0171360 A1
(43) Pub. Date: Jun. 18, 2026

(54) DUAL FREQUENCY PULSED PLASMA PROCESSING TREATMENTS

(71) Applicant: Applied Materials, Inc., Santa Clara, CA (US)

(72) Inventors: Chengyu WEN, Santa Clara, CA (US); Shinjae HWANG, Santa Clara, CA (US); Kishor KALATHIPARAMBIL, Santa Clara, CA (US); Zhechen WANG, Santa Clara, CA (US)

(21) Appl. No.: 19/346,742

(22) Filed: Oct. 1, 2025

Related U.S. Application Data
(60) Provisional application No. 63/733,978, filed on Dec. 13, 2024.
(60) Provisional application No. 63/829,692, filed on Jun. 24, 2025.

(51) Int. Cl. H01J 37/32; C23C 16/32; C23C 16/34; C23C 16/505; C23C 16/515; H01L 21/768

(52) U.S. Cl. CPC H01J 37/32146; C23C 16/505; C23C 16/515; H01J 37/32091; H01J 37/3244; H10W 20/033; H10W 20/054; C23C 16/32; C23C 16/34; H01J 2237/332

(57) ABSTRACT

A processing method includes depositing a first layer on a field region and sidewalls of a via of an interconnect structure, and treating the first layer by establishing a pulsed dual RF frequency CCP, where (i) the dual RF frequency CCP is formed using the first RF generator and a second RF generator coupled to a first electrode, (ii) the pulsed dual RF frequency CCP is formed by simultaneously delivering pulses of the first RF signal and the second RF signal at a pulsing frequency and a duty cycle to the first electrode, and (iii) the first RF frequency is greater than the second RF frequency.

### CROSS-REFERENCE TO RELATED APPLICATIONS

This application claims the benefit of and priority to U.S. Provisional Application No. 63/733,978, filed on Dec. 13, 2024, and U.S. Provisional Application No. 63/829,692, filed on Jun. 24, 2025, which are expressly incorporated by reference herein in their entirety as if fully set forth below and for all applicable purposes.

### BACKGROUND

### Field

Embodiments of the present invention relate to methods for manufacturing integrated circuit devices. More particularly, embodiments of the invention relate to forming metal interconnect structures using one or more cyclical deposition processes.

### Description of the Related Art

As the structure size of integrated circuit (IC) devices is scaled down to sub-quarter micron dimensions, electrical resistance and current densities have become an area for concern and improvement. Multilevel interconnect technology provides the conductive paths throughout an IC device, and are formed in high aspect ratio features, including contacts, plugs, vias, lines, wires, and other features. A typical process for forming an interconnect on a substrate includes depositing one or more layers, etching at least one of the layer(s) to form one or more features, depositing a barrier layer in the feature(s) and depositing one or more layers to fill the feature. Typically, a feature is formed within a dielectric material disposed between a lower conductive layer and an upper conductive layer. The interconnect is formed within the feature to link the upper and lower conductive layers. Reliable formation of these interconnect features is important to the production of the circuits and continued effort to increase circuit density and quality on individual substrates and die.

Copper is often a metal of choice for filling sub-micron high aspect ratio, interconnect features because copper and its alloys have lower resistivities than aluminum. However, copper diffuses more readily into surrounding materials and can alter the electronic device characteristics of the adjacent layers and, for example, form a conductive path between layers, thereby reducing the reliability of the overall circuit and may even result in device failure.

Barrier layers therefore, are deposited prior to copper metallization to prevent or impede the diffusion of copper atoms. Barrier layers typically contain a metal such as tungsten, titanium, tantalum, and nitrides thereof, which all have a greater resistivity than copper. To deposit a barrier layer within a feature, the barrier layer must be deposited on the bottom of the feature as well as the sidewalls thereof. Therefore, the additional amount of the barrier layer on the bottom of the feature not only increases the overall resistance of the feature, but also forms an obstruction between higher and lower metal interconnects of a multi-layered interconnect structure. It is desirable to form barrier layers that have a desired high density and include a minimal amount of unwanted contamination so as to improve the electrical resistance of the formed structure.

There is a need, therefore, for an improved apparatus and method for forming metal interconnect structures which minimizes the electrical resistance of the interconnect by improving the properties of the deposited barrier layer.

### SUMMARY

Embodiments of the disclosure include a processing method, comprising: depositing a first layer within a device feature formed on a substrate; and treating the first layer by establishing a dual RF frequency capacitively coupled plasma (CCP) in a plasma processing chamber. The process of treating the first layer comprises: delivering a plurality of process gases to a processing region of the plasma processing chamber, wherein the plurality of process gases comprises a first gas and a second gas; delivering a first RF power at a first RF frequency from a first RF generator to a first electrode of the plasma processing chamber; and delivering a second RF power at a second RF frequency from a second RF generator to the first electrode of the plasma processing chamber, wherein the delivering the first RF power and the second RF power comprises pulsing the first RF power and the second RF power at a first duty cycle and a first pulsing frequency, and the first RF frequency is greater than the second RF frequency.

Embodiments of the disclosure may further include a processing method, comprising treating a first layer formed in a device feature formed on a surface of a substrate. The process of treating the first layer comprises: establishing a dual RF frequency CCP in a plasma processing chamber, delivering a plurality of process gases to a processing region of the plasma processing chamber, wherein the plurality of process gases comprises a first gas and a second gas; delivering a first RF power at a first RF frequency from a first RF generator to a first electrode of the plasma processing chamber; and delivering a second RF power at a second RF frequency from a second RF generator to the first electrode of the plasma processing chamber. The delivering the first RF power and the second RF power comprises pulsing the first RF power and the second RF power at a first duty cycle and a first pulsing frequency. The first RF frequency is greater than the second RF frequency, and the dual RF frequency capacitively coupled plasma (CCP) is formed between the first electrode and the substrate that is disposed on a substrate supporting surface of a substrate support.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic cross-sectional views an example processing system, according to one or more embodiments.

FIG. 2 is a process flow diagram of a method for processing a substrate, according to one or more embodiments.

FIGS. 3A-3C are cross-sectional views of a portion of a substrate during a method for processing a substrate, according to one or more embodiments.

FIG. 4 illustrates graphs of radio frequency (RF) pulse waveforms generated during one or more of the methods described herein, according to one or more of the aspects described herein.

FIG. 5 is a process flow diagram of a method for processing a substrate, according to one or more embodiments.

FIGS. 6A-6D are cross-sectional views of a portion of a substrate during a method for processing a substrate, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

During conventional deposition, treatment, and removal processes used during middle-end-of-line (MEOL) and back-end-of-line (BEOL) stages of device manufacturing, a plasma is typically generated by use of a single radio frequency (RF) signal provided from a single RF source (i.e., a single RF frequency plasma). For example, during deposition and treatment of barrier layers or liner layers formed on sidewalls of vias and/or trenches formed in interconnect structures, and removal of a passivation layer formed within the vias and/or trenches, plasmas are typically generated by the delivery of an RF signal from a single RF source to an electrode within a processing chamber. Therefore, the plasmas used for deposition, treatment, and removal processes are restricted to being generated using the same fundamental RF frequency. If the generated plasma is too “strong” or “aggressive,” such as when the plasma contains highly energetic species and/or a high plasma density, then during deposition and removal processes, fragile layers within a structure, such as dielectric layers within an interconnect structure, can be damaged.

Embodiments of the present disclosure generally relate to a system and method for depositing and treating layers in device features formed in an interconnect structure or device contact structure. In some embodiments disclosed herein, a dual RF frequency plasma is generated during a treatment process performed after the formation of thin film layer, such as the formation of a tantalum nitride (TaN), titanium nitride (TiN), cobalt (Co), niobium (Nb), niobium nitride (NbN), niobium carbide (NbC), zirconium (Zr), zirconium nitride (ZrN), or other interconnect layer or contact formation layer formed by an atomic layer deposition (ALD) or chemical vapor deposition (CVD) process. In some other embodiments, a dual RF frequency plasma is generated during a treatment process performed to selectively remove at least a portion of a thin film layer, such as a layer that comprises a carbon-containing material. In one example, the treatment process includes a plasma process that will include the use of a pulsed multiple RF frequency generated plasma that is used to remove one or more layers in a minimally aggressive manner and/or improve the mechanical and electrical properties of a deposited layer(s) within an interconnect structure. The treatment process, which utilizes at least a pulsed dual RF frequency plasma for treating layers within the interconnect structure, is designed to control the ion energy generated in a capacitively coupled plasma (CCP) to prevent damage to the low-k dielectric layers found in the device features formed on the substrate during the plasma treatment process. The treatment process described herein can be especially useful in the treatment of all surfaces of high-aspect-ratio (HAR) structures, such as HAR structures greater than 1:3, while inducing minimal damage to the underlying structure.

### Substrate Processing System Example

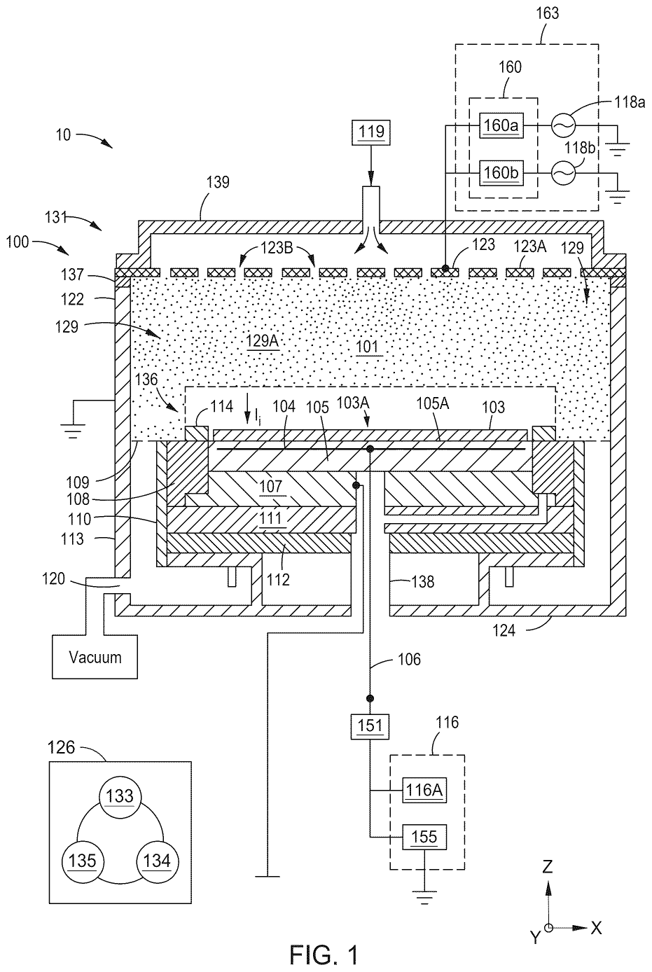

FIG. 1 is a schematic cross-sectional view of a processing system 10 that is configured to perform one or more of the plasma processing methods set forth herein. In some embodiments, the processing system 10 illustrated in FIG. 1 is configured for performing a plasma-assisted treatment process. However, it should be noted that the embodiments described herein may also be used with processing systems configured for use in other plasma-assisted processes, such as plasma-enhanced deposition processes, for example, plasma-enhanced chemical vapor deposition (PECVD) processes, plasma-enhanced physical vapor deposition (PEPVD) processes, plasma-enhanced atomic layer deposition (PEALD) processes, reactive ion etching (RIE) processes, or plasma-based ion implant processing, for example, plasma doping (PLAD) processing.

As shown in FIG. 1 the processing system 10 is configured to form a capacitively coupled plasma (CCP), where the processing system 10 includes an upper electrode (e.g., chamber lid 123) disposed in a processing volume 129 facing a lower electrode (e.g., the substrate support assembly 136) also disposed in the processing volume 129. A plasma generator assembly 163 is electrically coupled to one of the upper electrode or lower electrode to deliver an RF signal that is used to ignite and maintain a plasma 101 in a processing region 129A disposed over a substrate 103 with a substrate surface 103A. The plasma generator assembly 163 will generally include a first RF generator 118a, a second RF generator 118b, and an RF matching network 160. The RF matching network 160 will generally include a first RF match 160a coupled to the first RF generator 118a and a second RF match 160b coupled to the second RF generator 118b. In one example, the output of the RF matching network 160 (i.e., the outputs of the first RF match 160a and the second RF match 160b) are coupled to the upper electrode, such as a showerhead plate 123A. In some embodiments, the first RF generator 118a is configured to deliver an RF signal having a frequency that is greater than 400 kilohertz (kHz), such as an RF frequency ranging between 20 megahertz (MHz) and 120 MHz, such as about 60 MHz. The second RF generator 118b is configured to deliver an RF signal have a frequency that is greater than 400 kHz, such as an RF frequency ranging between 1 MHz and 20 MHz, such as about 13.56 MHz. In some embodiments, the first RF generator 118a generates an RF signal that has a higher RF frequency than the second RF generator 118b.

The processing system 10 further includes a processing chamber 100, a substrate support assembly 136, and a system controller 126. The processing chamber 100 typically includes a chamber body 113 that includes the chamber lid 123, one or more sidewalls 122, and a chamber base 124, which collectively define the processing volume 129. A substrate 103 is loaded into, and removed from, the processing volume 129 through an opening (not shown) in one of the one or more sidewalls 122, which is sealed with a slit valve (not shown) during plasma processing of the substrate 103. The one or more sidewalls 122 and chamber base 124 generally include materials that are sized and shaped to form the structural support for the elements of the processing chamber 100 and are configured to withstand the pressures and added energy applied to them while a plasma 101 is generated within a vacuum environment maintained in the processing volume 129 of the processing chamber 100 during processing. In one example, the one or more sidewalls 122 and chamber base 124 are formed from a metal, such as aluminum, an aluminum alloy, or a stainless steel alloy. In some embodiments, there is a dielectric coating on the sidewalls 122. The dielectric coating can be anodized aluminum, aluminum oxide, yttrium oxide, mixtures thereof. The thickness of the dielectric coating can vary from 1 nanometers (nm) to 10 centimeters (cm).

The system controller 126, also referred to herein as a processing chamber controller, includes a central processing unit (CPU) 133, a memory 134, and support circuits 135. The system controller 126 is used to control the process sequence used to process the substrate 103, including the substrate biasing methods described herein. The CPU 133 is a general-purpose computer processor (or processors) configured for use in an industrial setting for controlling the processing chamber and sub-processors related thereto. The memory 134 described herein, which is generally non-volatile memory, may include random access memory, read-only memory, floppy or hard disk drive, or other suitable forms of digital storage, local or remote. The support circuits 135 are conventionally coupled to the CPU 133 and comprise cache, clock circuits, input/output subsystems, power supplies, and the like, and combinations thereof. Software instructions (program) and data can be coded and stored within the memory 134 for instructing a processor within the CPU 133. A software program (or computer instructions) readable by CPU 133 in the system controller 126 determines which tasks are performable by the components in the processing system 10. Typically, the program, which is readable by CPU 133 in the system controller 126, includes code, which, when executed by the processor (CPU 133), performs tasks relating to the plasma processing schemes described herein. The program may include instructions that are used to control the various hardware and electrical components within the processing system 10 to perform the various process tasks and various process sequences used to implement the methods described herein. In one embodiment, the program includes instructions that are used to perform one or more of the operations described below.

The substrate support assembly 136, which generally includes the substrate support 105 (e.g., electrostatic-chuck (ESC) substrate support) and support base 107, is disposed on a support shaft 138 that is grounded and extends through the chamber base 124. In some embodiments, the substrate support assembly 136 can additionally include an insulator plate 111 and a ground plate 112. The support base 107 is electrically isolated from the chamber base 124 by the insulator plate 111, and the ground plate 112 is interposed between the insulator plate 111 and the chamber base 124. The substrate support 105 is thermally coupled to and disposed on the support base 107. In some embodiments, the support base 107 is configured to regulate the temperature of the substrate support 105, and the substrate 103 disposed on the substrate support 105, during substrate processing. In some embodiments, the support base 107 includes one or more cooling channels (not shown) disposed therein that are fluidly coupled to, and in fluid communication with, a coolant source (not shown), such as a refrigerant source or water source having a relatively high electrical resistance. In some embodiments, the substrate support 105 includes a heater (not shown), such as a resistive heating element embedded in the dielectric material thereof. Herein, the support base 107 is formed of a corrosion-resistant thermally conductive material, such as a corrosion-resistant metal, for example aluminum, an aluminum alloy, or a stainless steel and is coupled to the substrate support with an adhesive or by mechanical means.

In some alternate embodiments of FIG. 1, the plasma generator assembly 163 and its components (e.g., the first RF generator 118a, second RF generator 118b, and RF matching network 160) are coupled to the support base 107 or bias electrode 104 instead of the showerhead plate 123A.

In some embodiments, the processing chamber 100 further includes the quartz pipe 110, or collar, that at least partially circumscribes portions of the substrate support assembly 136 to prevent the substrate support 105 and/or the support base 107 from contact with corrosive processing gases or plasma, cleaning gases or plasma, or byproducts thereof. Typically, the quartz pipe 110, the insulator plate 111, and the ground plate 112 are circumscribed by a cathode liner 108. In some embodiments, a plasma screen 109 is positioned between the cathode liner 108 and the sidewalls 122 to prevent plasma from forming in a volume underneath the plasma screen 109 between the cathode liner 108 and the one or more sidewalls 122.

In some embodiments, the substrate support 105 is formed of a metal plate that is grounded. In some other embodiments, the substrate support 105 is formed of a dielectric material, such as a bulk sintered ceramic material, such as a corrosion-resistant metal oxide or metal nitride material, for example, aluminum oxide (Al₂O₃), aluminum nitride (AlN), titanium oxide (TiO), titanium nitride (TiN), tantalum nitride (TaN), yttrium oxide (Y₂O₃), mixtures thereof, or combinations thereof. In embodiments herein, the substrate support 105 further includes the bias electrode 104 embedded in the dielectric material thereof. In one configuration, the bias electrode 104 is a chucking pole used to secure (i.e., chuck) the substrate 103 to the substrate support surface 105A of the substrate support 105 and to bias the substrate 103 with respect to the plasma 101 using one or more of the pulsed-voltage biasing sources (not shown), which comprise a voltage waveform generator (e.g., variable direct current (DC)/alternating current (AC) source). Typically, the bias electrode 104 is formed of one or more electrically conductive parts, such as one or more metal meshes, foils, plates, or combinations thereof.

In some embodiments, the upper electrode assembly 131 includes the upper electrode (e.g., showerhead plate 123A of the chamber lid 123) and a lid plate 139, which are configured to form a showerhead assembly that is configured to evenly distribute one or more gases provided from the processing gas source 119 to the process region 129A through a plurality of holes 123B formed in the upper electrode. The processing volume 129 is fluidly coupled to one or more dedicated vacuum pumps through a vacuum outlet 120, which maintains the processing volume 129 at sub-atmospheric pressure conditions and evacuate processing and/or other gases, therefrom.

In some embodiments, the chamber lid 123 and substrate support assembly 136 are configured in a parallel plate like configuration, such that the showerhead plate 123A of the chamber lid 123 is substantially parallel to the substrate support surface 105A of the substrate support assembly 136. The showerhead plate 123A can include a conductive metal plate that includes a plurality of holes 123B that are configured to distribute a process gas delivered from the processing gas source 119. In some alternate embodiments, the chamber lid 123 has a low angled concave conical shape or slightly curved concave shape relative to the flat substrate support assembly 136, which is centered about the center of chamber lid 123.

The overall control of the delivery of the first RF generator 118a and the second RF generator 118b are controlled by use of signals provided from the system controller 126. For example, the plasma generator assembly 163 is generally configured to deliver a desired amount of a continuous wave (CW) or pulsed RF power at different waveform frequencies to a portion of the chamber lid 123 for different plasma processing steps based on the control signals provided from the system controller 126.

However, in some embodiments, the system controller 126 is configured to cause the first RF generator 118a and the second RF generator 118b to provide pulses of RF power from each of the generators to an electrode in a process chamber, such as the showerhead plate 123A of the chamber lid 123. In some embodiments, the pulsed RF signals provided by the first RF generator 118a (e.g., 60 MHz RF signal) and the second RF generator 118b (e.g., 13.56 MHz RF signal) are synchronized. The pulsed RF signals can have a pulse duty cycle that is between about 1% and 99%, such as a duty cycle of about 10% to about 80%, or about 50% to about 75%, and a pulsing frequency that is between about 1 kHz and 100 kHz during a treatment process performed after a layer is deposited on device features formed within a surface of the substrate. The RF power provided by a first RF generator 118a that is providing a high RF frequency signal (e.g., 60 MHz RF signal) to a CCP electrode (e.g., showerhead plate 123A) is between about 50 watts (W) and about 1000 W, such as between about 800 W and 1000 W, and RF power provided by a second RF generator 118b that is providing a lower RF frequency signal (e.g., 13.56 MHz RF signal) to the CCP electrode is between about 50 W and about 1000 W, such as between about 200 W and 1000 W, or even between about 200 W and 800 W. In some embodiments, the RF power provided by the first RF generator 118a that is providing a high RF frequency signal (e.g., 60 MHz RF signal) to the CCP electrode is greater than the RF power provided by the second RF generator 118b that is providing a low RF frequency signal (e.g., 13.56 MHz RF signal) to the CCP electrode.

The process gases provided during a pulsed plasma treatment can include a mixture of two or more process gases that are configured to remove contamination from a deposited film layer, improve the properties of the deposited layer by use of the treatment process, and minimize the amount of damage provided to the layers that form the device features formed in the surface of the substrate. In some embodiments, the process gas mixture includes a reducing gas, such as hydrogen (H₂), and an inert gas such as argon (Ar), xenon (Xe) or krypton (Kr). In one embodiment, the process gas mixture includes hydrogen (H₂), and argon (Ar) that are provided at a desired Ar to H₂ ratio (e.g., Ar/H₂ ratio). In one example, the Ar/H₂ ratio used during a treatment process is between 0.0001 and 0.1, such as between 0.0010 and 0.0045.

Referring to FIG. 1 the substrate support assembly 136 an edge ring 114 positioned within a region of the substrate support 105. For example, the edge ring 114 is disposed on and adjacent to the substrate support 105. In this configuration, the edge ring 114 is formed from a semiconductor or dielectric material (e.g., AlN, etc.).

As noted above, in some embodiments, the bias electrode 104 is electrically coupled to a clamping network 116, which provides a chucking voltage thereto, such as static DC voltage between about −5000 V and about 10,000 V, using an electrical conductor, such as the coaxial power delivery line 106 (e.g., a coaxial cable). The application of a sufficient clamping voltage to the bias electrode 104 can facilitate the temperature control of the substrate 103 and the edge ring 114. The clamping network 116 includes bias compensation circuit elements 116A, and a DC power supply 155. In some embodiments, the clamping network is coupled to an RF filter assembly 151 that is configured to block the RF signal generated by the plasma generator assembly 163 and any associated harmonics, from making their way to the clamping network 116 or the DC power supply 155.

The upper electrode assembly 131 is also positioned on, and electrically isolated from, the grounded sidewalls 122 by a lid insulator 137. As shown in FIG. 1, one or more components of the substrate support assembly 136, such as the support base 107 are grounded. As shown in FIG. 1, an upper electrode, such as the showerhead plate 123A of the chamber lid 123, is electrically coupled to the plasma generator assembly 163, which is configured to ignite and maintain a plasma 101 in a processing region formed therebetween. In some embodiments, as noted above, the plasma generator assembly 163 is generally configured to deliver a desired amount of a pulsed RF power at different waveform frequencies to the chamber lid 123 for different plasma processing steps based on control signals provided from the system controller 126. Stated differently, the plasma generator assembly 163 is able to provide pulsed RF signals at at least two different RF frequencies by enabling the RF generators during processing to effectively modulate the ion flux and ion energy provided by the plasma to reach the optimum regime during plasma processing.

### Substrate Processing Sequences

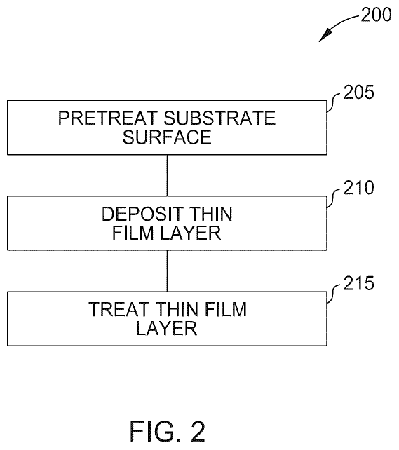

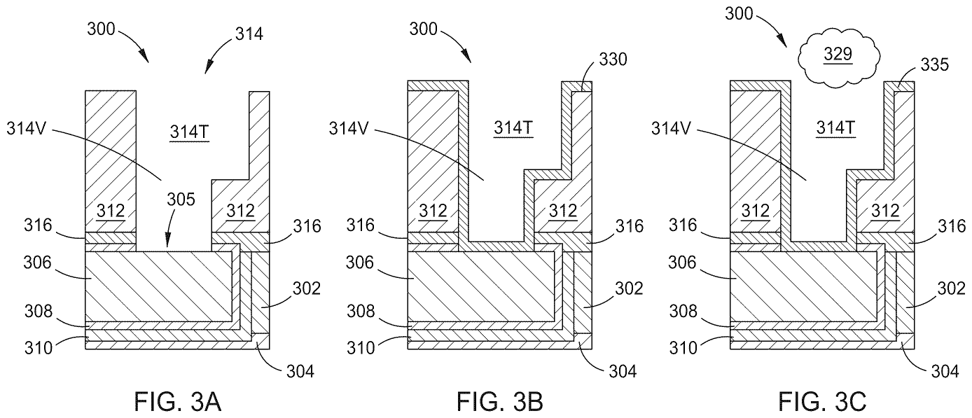

FIG. 2 is a process flow diagram of a first method 200 of processing a substrate, according to one or more embodiments. FIGS. 3A-3C are cross-sectional views of a portion of a substrate during a method for processing a substrate, according to one or more embodiments. In some embodiments, the first method 200 is configured to treat a deposited layer to improve the electrical and/or mechanical properties of the deposited layer from its as-deposited state. The first method 200 processes described herein can be especially useful for treating thin-film layers that are formed over structures that are susceptible to plasma-induced damage, such as low-k dielectric films or epitaxial layers.

It should be understood that FIGS. 3A-3C illustrate only partial schematic views of the substrate, and the substrate may contain any number of device structures and additional materials having aspects as illustrated in the figures. It should also be noted that although the method illustrated in FIG. 2 is described sequentially, other process sequences that include one or more operations that have been omitted and/or added, and/or has been rearranged in another desirable order, fall within the scope of the embodiments of the disclosure provided herein.

The term “substrate” as used herein refers to a layer of material that serves as a basis for subsequent processing operations and includes a surface to be cleaned. The substrate may be a silicon based material or any suitable insulating materials or conductive materials as needed. The substrate may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

The first method 200 begins at operation 205 by performing a first processing operation on a substrate, which includes providing a substrate that includes one or more device features 314 formed in a surface of the substrate. The one or more device features 314 may include a bottom surface 305. In one example, as shown in FIG. 3A, the substrate includes an interconnect structure 300 that includes a first dielectric layer 302 formed on the substrate. The first dielectric layer 302 may be formed of a dielectric material, such as a low k dielectric, silicon dioxide (SiO₂), silicon nitride (Si₃N₄), silicon carbide (SiC), aluminum oxide (Al₂O₃), or aluminum nitride (AlN). In some embodiments, the low-k dielectric material can include one or more silicon oxide (SiOx), silicon nitride (SiN), and silicon carbonitride (SiCN), or silicon carbonoxyntride (SiOCN) material. A first etch stop layer 304 may be disposed between the first dielectric layer 302 and the substrate. The interconnect structure 300 further includes a conductive layer 306 embedded within the first dielectric layer 302 and separated from the first dielectric layer 302 by a liner layer 308 and a barrier layer 310. The conductive layer 306 may be formed of copper (Cu), cobalt (Co), molybdenum (Mo), tungsten (W), or ruthenium (Ru). The liner layer 308 may be formed of Ru, Co, or ruthenium and cobalt (RuCo). The barrier layer 310 may be formed of tantalum nitride (TaN) or doped tantalum nitride (TaN). The interconnect structure 300 further includes a second dielectric layer 312, having one or more device features 314, such as a via 314V and a trench 314T formed therein, over the first dielectric layer 302 and the conductive layer 306. The second dielectric layer 312 may be formed of the same material as the first dielectric layer 302, such as low k dielectric carbon-doped silicon oxycarbide (SiCOH), silicon dioxide (SiO₂), silicon nitride (Si₃N₄), silicon carbide (SiC), aluminum oxide (Al₂O₃), or aluminum nitride (AlN). In another embodiment, the second dielectric layer 312 may be formed of a different material from the first dielectric layer 302, while maintaining the same low-k properties. A second etch stop layer 316 may be disposed between the second dielectric layer 312 and the first dielectric layer 302.

Operation 205 can also optionally include a pretreatment process in which contaminants and oxide layers are removed from one or more of the exposed surfaces of the interconnect structure 300 and device feature 314. In some embodiments, the semiconductor device structure is exposed to a pretreatment process that includes processes to remove one or more native oxide or contamination removal processes for removing the contamination and/or native oxide layer (if present). The pretreatment process of operation 205 of can include one or more dry clean processes. Any suitable dry clean process may be performed. The dry clean process may include a radical treatment or plasma process, such as a two-part dry chemical clean process using nitrogen trifluoride (NF₃) and ammonia (NH₃), and hydrogen (H₂) and oxygen (O₂) plasma etch process, an H₂ plasma etch process, or a combination thereof.

As shown in FIG. 3B, at operation 210, a second processing operation that includes depositing a barrier layer 330 on the field region of the second dielectric layer 312, the inner sidewalls of the via 314V and the trench 314T is performed. In some embodiments, the barrier layer 330 can include a silicide layer that is used to form part of a metal-oxide-semiconductor field-effect transistor (MOSFET) device contact. In other embodiments, the barrier layer 330 can include a liner or diffusion layer that is used to form part of a middle-of-the-line (MOL) or backend-of-the-line (BEOL) interconnect structure. The second processing operation may be performed in the processing chamber 100 or a separate processing chamber. The deposition process can include an ALD or CVD deposition process in which a precursor gas (e.g., metal containing precursor gas) and carrier gas (e.g., He, H₂, Ar, or N₂) are provided to the surface of the substrate disposed in the processing chamber. The barrier layer 330 may be formed of tantalum nitride (TaN) or doped tantalum nitride (TaN), metal doped TaN, titanium nitride (TiN), niobium nitride (NbN), niobium carbide (NbC), tungsten nitride (WN), or tungsten nitride carbide (WCN).

At operation 215, a dual RF frequency treatment process is established to perform a plasma processing operation on the substrate. The dual RF frequency treatment process can include the generation of a dual RF frequency capacitively coupled plasma (CCP). In one or more examples, as shown in FIG. 3C, the second processing operation includes, generating a dual RF frequency CCP plasma 329 to treat the barrier layer 330, forming a treated barrier layer 335. In one or more embodiments, process gasses used to treat the barrier layer include, but are not limited to, hydrogen, helium, argon, and combinations thereof. As noted above, the processes gases can include two or more gases provided at a desired gas ratio (e.g., Ar/H₂). In one example, the Ar/H₂ ratio used during a treatment process performed during operation 215 is between 0.005 and 15.

In an effort to precisely control the amount of energy provided to a surface of a substrate during operation 215, to not damage one or more underlying layers and also precisely control the penetration depth of the formed plasma within device features 314, such as a trench 314T (FIG. 3C) formed on a surface of a substrate, a synchronized pulsed plasma is utilized. It has been found that continuous wave (CW) RF generated plasmas are generally unable to generate low enough average ion energies in a plasma, while still being able to sustain a plasma during processing, that will prevent damage to a deposited layer or underlying layers during one or more phases of a plasma process. In one or more embodiments of the disclosure provided herein, a dual RF CCP plasma 329 is generated by enabling the generation of a dual RF pulsed plasma by use of both the first RF generator 118a and the second RF generator 118b using control signals provided by the system controller 126. For example, the system controller 126 enables (activates) a RF pulsing recipe that is performed by the first RF generator 118a and the second RF generator 118b. In some embodiments, the first RF generator 118a and the second RF generator 118b each provide a pulsed RF signal to the upper electrode (i.e., the chamber lid 123) at different RF frequencies, forming a pulsed dual RF frequency capacitively couple plasma (CCP). In some embodiments, the first RF signal is modulated by the second RF signal prior to reaching the upper electrode of the processing chamber, forming the dual RF frequency CCP.

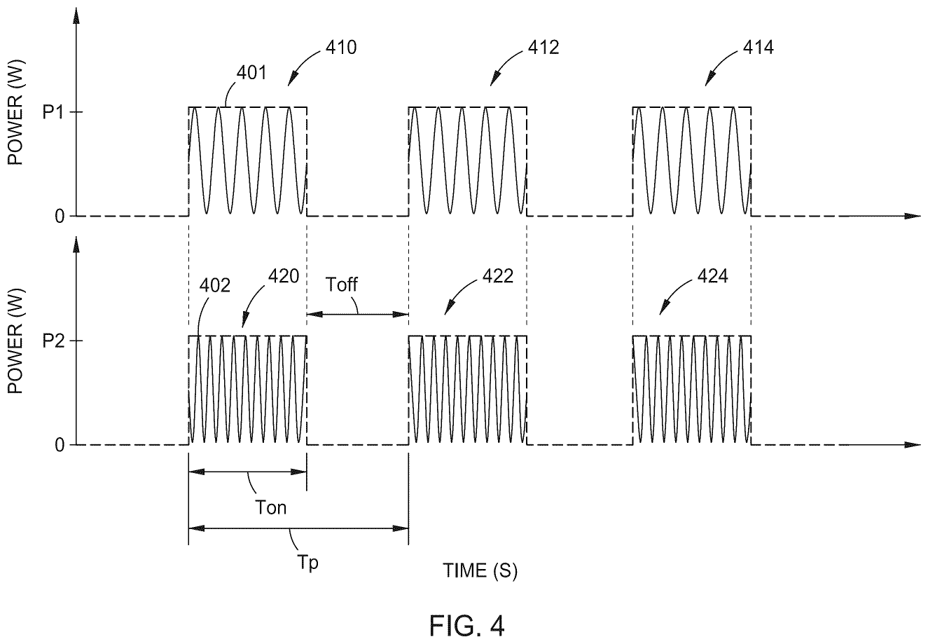

FIG. 4 illustrates a first RF waveform 401 used to form part of a dual frequency pulsed RF plasma that includes multiple RF waveform bursts 410, 412, and 414 that are delivered by the first RF generator 118a at a RF power P1, and a second RF waveform 402 used to form an additional part of the dual frequency pulsed RF waveform that includes multiple RF waveform bursts 420, 422, and 424 that are delivered by the second RF generator 118b at a RF power P2. It is to be understood that each burst described herein may include an RF waveform provided at a fundamental RF frequency provided by their respective RF generator. Each burst 410, 412, and 414 and each burst 420, 422, and 424 will include a burst period (Tₚ) that includes a burst on-time (Tₒₙ) portion and a burst off-time (T_{off}) portion. Each burst 410, 412, and 414 and burst 420, 422, and 424 can include a pulse duty cycle (i.e., Tₒₙ/Tₚ) that is between 1% and 99%, such as between 10% and 90%, 10% and 50%, or in some alternate cases between 50% and 75%. The bursts 410-414 and bursts 420-424 can each have a RF power level greater than 10 Watts that is provided at a desired fundamental RF frequency and be provided at pulsing frequency of between 10 Hz and 500 kHz, such as between 1 kilohertz (kHz) and 400 kHz, or between 10 kHz and 100 kHz. For example, the bursts 410, 412, and 414 may be provided at a first fundamental RF frequency of 60 megahertz (MHz), a first RF power level P1 (FIG. 4) of between 100 and 1000 W, and may be generated at a pulsing frequency between 10 kHz and 100 kHz. In one example, the on-time of the bursts 410, 412, and 414 may be between about 0.5 μs and 50 μs. In another example, the bursts 420, 422, and 424 may be provided at a first fundamental RF frequency of 13.56 MHz, a second RF power level P2 (FIG. 4) of between 100 and 1000 W, and may be similarly generated at a pulsing frequency between 10 kHz and 100 kHz.

In some embodiments, the bursts 410-414 and bursts 420-424 can be synchronized so that the start and/or the end of each of the bursts have a controlled RF waveform delivery relationship between each other. Each of the RF waveform generators may be synchronized using a synchronization transistor-transistor logic (TTL) signal and may be based, for example, on a rising edge of a falling edge of the synchronization TTL signal. As shown in FIG. 4, in some embodiments, the bursts 410-414 and bursts 420-424 are synchronized so that the bursts start at the same time and have the same pulse duration (i.e., burst on-time (Tₒₙ)). However, in some embodiments, the bursts 410-414 and bursts 420-424 are synchronized so that the bursts start at different times, have different pulse durations and/or have different applied RF waveform power levels (e.g., RF power P1 or P2).

In one processing example, the second RF generator 118b is configured to generate an RF signal with a frequency equal to 13.56 MHz or less, while the first RF generator 118a is configured to generate an RF signal with a frequency greater than 13.56 MHz (e.g., 60 MHz) during operation 215. The dual RF frequency CCP plasma may be pulsed at a frequency between 1 kHz and 100 kHz for a processing period of between 1 and 60 seconds in a processing chamber such as processing chamber 100 maintained at a chamber pressure between 0.1 and 20 Torr, for example 0.5-2 Torr. The RF power provided by a first RF generator 118a that is providing a high RF frequency signal (e.g., 60 MHz RF signal) to a CCP electrode (e.g., showerhead plate 123A) is between about 50 watts (W) and about 1000 W, such as between about 800 W and 1000 W, and RF power provided by a second RF generator 118b that is providing a lower RF frequency signal (e.g., 13.56 MHz RF signal) to the CCP electrode is between about 50 W and about 1000 W, such as between about 200 W and 800 W. The provided pulsed RF signals can have a pulse duty cycle that is between about 5% and 95%, such as a duty cycle of about 10% to about 50%, while the pulsing frequency is maintained at about 10 kHz to about 100 kHz during operation 215. Advantageously, generating a pulsed dual RF CCP plasma allows for effective modulation of the ion flux and energy to allow for the optimum regime to treat the deposited barrier layer 330 while providing minimal damage to the second dielectric layer 312 (i.e. the low-k material).

In one processing example, after operation 210 is used to deposit a metal layer, such as a metal layer that comprises titanium (Ti), tungsten (W), molybdenum (Mo), ruthenium (Ru), niobium (Nb), zirconium (Zr), or cobalt (Co), a dual frequency pulsed plasma process can be performed on the metal layer to improve its electrical and/or mechanical properties but simultaneously minimizing the redistribution of the deposited metal layer and damage to the underlying structure. During the performance of operation 215, it has been found that a dual-frequency pulsed plasma that includes providing a high RF frequency signal, such as a 60 MHz RF signal, to a CCP electrode at a power level of between about 100 W and 800 W, and providing a lower RF frequency signal, such as a 13.56 MHz RF signal, to the CCP electrode at a power level of between about 100 W and 300 W in a pulsed RF signal mode that each have a synchronized pulse duty cycle that is between about 50% and 75% and are provided at a pulsing frequency in a range between 10 kHz and about 100 kHz while providing a hydrogen (H₂) and argon (Ar) gas mixture at an Ar/H₂ ratio of between 0.005 and 15 at a chamber pressure of between 0.5 and 5 Torr for a total processing period of between 10 and 60 seconds provides a desirable amount of metal layer property improvement (e.g., densification, improved resistivity, etc.) while inducing minimal damage to the underlying structure, which includes fragile materials, such as a low-k material.

After the completion of operation 215, one or more subsequent processing steps can be performed on the substrate to fill the device feature 314 with a conductive material to form an interconnect. In some embodiments, one or more metal layers comprising Ti, Mo, W, Ru, Zr, Nb or other useful metal may be formed directly on the exposed portions of the layer formed in operation 210 to form the interconnect structure (e.g., MOL interconnect).

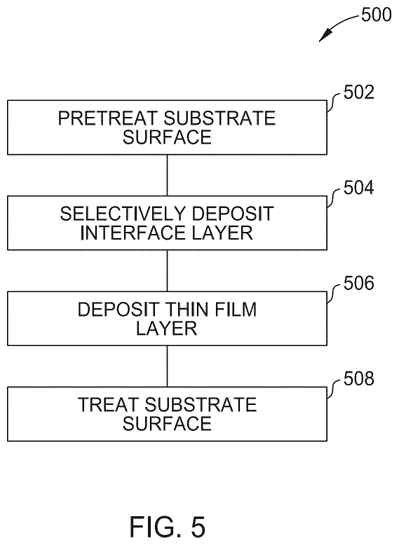

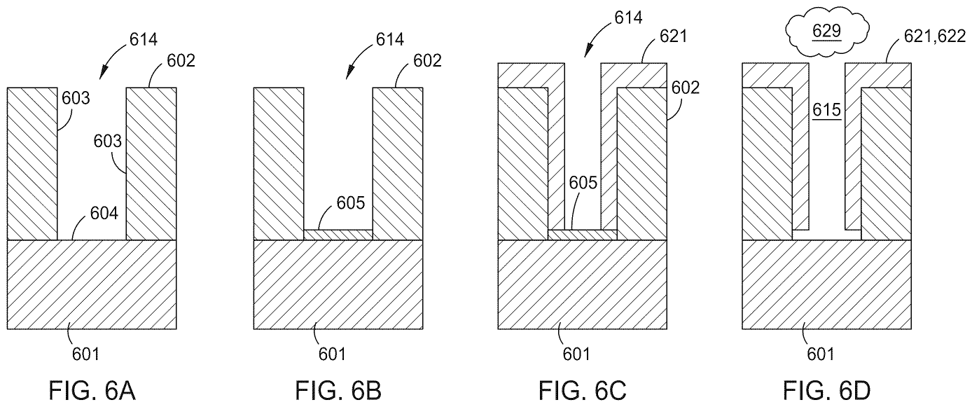

FIG. 5 is a process flow diagram illustrating a second method 500 of processing a substrate, according to one or more embodiments. FIGS. 6A-6C are cross-sectional views of a portion of a substrate during the performance of the second method 500, according to one or more embodiments. In some embodiments, the second method 500 is configured to treat and selectively remove a layer of material disposed within a device feature formed on a surface of a substrate. The second method 500 processes described herein can be especially useful for treating thin-film layers that are formed within a lower portion or bottom region of a device feature formed in a surface of a substrate without damaging the field (e.g., top-surface) and side wall regions of the device features due to the exposure to the plasma during processing.

FIGS. 6A-6D are partial schematic views of the substrate during the various operations performed during the second method 500. It should also be noted that although the method illustrated in FIG. 5 is described sequentially, other process sequences that include one or more operations that have been omitted and/or added, and/or has been rearranged in another desirable order, fall within the scope of the embodiments of the disclosure provided herein.

The second method 500 begins at operation 502 by performing a first processing operation on a substrate, which includes providing a substrate that includes one or more device features 614 formed in a surface of the substrate. In one example, as shown in FIG. 6A, the substrate includes a structure that includes a device feature 614 that is formed within a first dielectric layer 602 formed on a substrate 601. The first dielectric layer 602 may include a dielectric material, such as low k dielectric carbon-doped silicon oxycarbide (SiCOH), silicon dioxide (SiO₂), silicon nitride (Si₃N₄), silicon carbide (SiC), aluminum oxide (Al₂O₃), or aluminum nitride (AlN). The substrate 601 may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

The device feature 614 formed in the first dielectric layer 602 can include sidewalls 603 and a bottom surface 604. The bottom surface 604 can include a portion of an interconnect structure, such a region that includes one or more conductive layers (e.g., Cu, Mo, W, Ru or other material), and/or a portion of a contact structure that can include a source/drain region of MOSFET type of device, which can in a silicon (Si) or silicon germanium (SiGe) containing region.

Operation 502 can also optionally include a pretreatment process in which contaminants and oxide layers are removed from one or more of the exposed surfaces of the substrate 601 and device feature 614. In some embodiments, the semiconductor device structure is exposed to a pretreatment process that includes a contamination removal process for removing surface contamination and/or a formed native oxide layer (if present). The pretreatment process of operation 502 can include one or more dry clean processes. The dry clean process may include a radical treatment or plasma process, such as a two-part dry chemical clean process using NF₃ and NH₃, and H₂ and O₂ plasma etch process, an H₂ plasma etch process, or a combination thereof.

As shown in FIG. 6B, at operation 504, a second processing operation is performed that includes selectively depositing a masking layer 605 on the bottom surface 604, which is positioned at the bottom of the device feature 614 to mask the underlying material layer(s). The second processing operation 504 may be performed in the processing chamber 100 or a separate processing chamber. The deposition process can include an ALD, CVD, or spin-on deposition process in which a precursor (e.g., liquid or gas) is provided to the surface of the substrate disposed in the processing chamber to selectively form the masking layer 605 on a portion thereof. The masking layer 605 may be formed of a carbon-containing material configured to selectively bond to one or more of the materials formed positioned on the bottom surface 604. In one example, the masking layer 605 includes an organic material such as a self-assembled-monolayer material. In one example, the self-assembled monolayer (SAM) layer comprises alkyl chain molecules (e.g., alkanethiols).

As shown in FIG. 6C, at operation 506, a third processing operation that includes depositing a diffusion barrier layer 621 on the field region of the second dielectric layer 312, and the sidewalls 603 of the device feature 614 is performed. The second processing operation may be performed in the processing chamber 100 or a separate processing chamber. The deposition process can include an ALD or CVD deposition process in which a precursor gas (e.g., metal containing precursor gas) and carrier gas (e.g., He, H₂, Ar, or N₂) are provided to the surface of the substrate disposed in the processing chamber. The diffusion barrier layer 621 may be formed of tantalum nitride (TaN) or doped tantalum nitride (TaN), metal doped TaN, titanium nitride (TiN), niobium nitride (NbN), niobium carbide (NbC), tungsten nitride (WN), or tungsten nitride carbide (WCN). As shown in FIG. 6C, the presence of the masking layer 605 is used to prevent or inhibit the growth of the diffusion barrier layer 621 on or over the bottom surface 604 of the device feature 614.

At operation 508, a dual RF frequency treatment process is established to perform a plasma processing operation on the substrate. In one or more examples, as shown in FIG. 6D, operation 508 includes generating a dual RF frequency CCP plasma 629 to treat and remove the masking layer 605 from the bottom of the device feature 614 through the channel 615 (e.g., gap), and in some cases also simultaneously forming a treated diffusion barrier layer 622. In one or more embodiments, process gases used to treat the barrier layer include, but are not limited to, hydrogen, helium, argon, and combinations thereof. As noted above, the process gases can include two or more gases provided at a desired gas ratio (e.g., Ar/H₂).

As noted above, to precisely control the amount of energy provided to a surface of a substrate during a plasma process to not damage one or more underlying layers and also precisely control the penetration depth of the formed plasma within device features 614 a synchronized pulsed plasma is utilized. In one or more embodiments of the disclosure provided herein, a dual RF CCP plasma 629 is generated by enabling the generation of a dual RF pulsed plasma by use of both the first RF generator 118a and the second RF generator 118b using control signals provided by the system controller 126.

In some embodiments of operation 508, the second RF generator 118b is configured to generate an RF signal with a frequency equal to 13.56 MHz or less, while the first RF generator 118a is configured to generate an RF signal with a frequency greater than 13.56 MHz (e.g., 40 MHz, 60 MHz, 120 MHz, etc.) during operation 508. The dual RF frequency CCP plasma may be pulsed at a frequency between 10 kHz and 100 kHz for a processing period of between 1 and 60 seconds in a processing chamber such as processing chamber 100 maintained at a chamber pressure between 0.1 and 15 Torr, for example 5 to 15 Torr. The RF power provided by a first RF generator 118a that is providing a high RF frequency signal (e.g., 60 MHz RF signal) to a CCP electrode (e.g., showerhead plate 123A) is between about 50 ) and about 1000 W, such as between about 800 W and 1000 W, and RF power provided by a second RF generator 118b that is providing a lower RF frequency signal (e.g., 13.56 MHz RF signal) to the CCP electrode is between about 50 W and about 1000 W, such as between about 200 W and 800 W. The provided pulsed RF signals can have a pulse duty cycle that is between about 5% and 95%, such as a duty cycle of about 10% to about 50%, while the pulsing frequency is maintained at about 10 kHz to about 100 kHz during operation 215. Advantageously, generating a pulsed dual RF CCP plasma allows for effective modulation of the ion flux and energy to allow for the optimum regime to treat the deposited masking layer 605 and barrier layer 622 while providing minimal damage to the second dielectric layer 312 (i.e. the low-k material).

In one processing example, after operation 506 is used to deposit a masking layer 605, a dual-frequency pulsed plasma process is performed on the substrate to remove a portion of the masking layer 605 while minimizing the damage to the underlying structure. During the performance of operation 508, it has been found that a dual-frequency pulsed plasma that includes providing a high RF frequency signal, such as a 60 MHz RF signal, to a CCP electrode at a power level of between about 400 W and 1000 W, and providing a lower RF frequency signal, such as a 13.56 MHz RF signal, to the CCP electrode at a power level of between about 100 W and 300 W in a pulsed RF signal mode that each have a synchronized pulse duty cycle that is between about 50% and 75% and are provided at a pulsing frequency in a range between 10 kHz and about 100 kHz while providing a hydrogen (H₂) and argon (Ar) gas mixture at a chamber pressure less than 15 Torr, such as between 5 and 15 Torr, for a total processing period of between 10 and 60 seconds provides a desirable amount of material removal at the bottom of high aspect ratio device features (e.g. 1:3 device features), while inducing minimal damage to the underlying structure, which includes fragile materials, such as a low-k material.

At the completion of operation 508 one or more subsequent processing steps can be performed on the substrate to fill the device feature 614 with a conductive material to form an interconnect or contact structure. In some embodiments, one or more metal layers comprising Ti, Mo, W, Ru, Zr, Nb, or other useful metal is formed directly on the bottom surface 604 to form the interconnect structure (e.g., MOL interconnect) or device contact structure (e.g., silicide layer and fill metal).

While the foregoing is directed to embodiments of the present disclosure, other and further embodiments of the disclosure may be devised without departing from the basic scope thereof, and the scope thereof is determined by the claims that follow.

What is claimed is:

1. A processing method, comprising:
depositing a first layer within a device feature formed on a substrate; and
treating the first layer by establishing a dual radio frequency (RF) capacitively coupled plasma (CCP) in a plasma processing chamber, wherein treating the first layer comprises:
delivering a plurality of process gases to a processing region of the plasma processing chamber, wherein the plurality of process gases comprises a first gas and a second gas;
delivering a first RF power at a first RF frequency from a first RF generator to a first electrode of the plasma processing chamber; and
delivering a second RF power at a second RF frequency from a second RF generator to the first electrode of the plasma processing chamber, wherein:
the delivering the first RF power and the second RF power comprises pulsing the first RF power and the second RF power at a duty cycle and a pulsing frequency; and
the first RF frequency is greater than the second RF frequency.

2. The method of claim 1, wherein the plurality of process gases are selected from a group comprising a reducing gas and an inert gas.

3. The method of claim 1, wherein the first gas comprises hydrogen (H₂) and the second gas comprises argon (Ar).

4. The method of claim 3, wherein the first gas and the second gas are provided at a second gas to first gas ratio that is between about 0.0001 and about 0.1.

5. The method of claim 3, wherein the pulsing frequency is between 10 kilohertz (kHz) and 100 kHz.

6. The method of claim 5, wherein the first RF frequency is greater than 13.56 megahertz (MHz) and the second RF frequency is less than or equal to 13.56 MHz.

7. The method of claim 1, wherein the first RF frequency is greater than 13.56 megahertz (MHz) and the second RF frequency is less than or equal to 13.56 MHz.

8. The method of claim 7, wherein the pulsing frequency is between 10 kilohertz (kHz) and 100 KHz.

9. The method of claim 1, wherein the first electrode comprises a showerhead and wherein the dual RF frequency capacitively coupled plasma (CCP) is formed between the showerhead and the substrate which is disposed on a substrate supporting surface of a substrate support.

10. The method of claim 1, wherein the first layer comprises at least one of tantalum nitride (TaN), titanium nitride (TiN), niobium nitride (NbN), niobium carbide (NbC), or tungsten nitride (WN).

11. The method of claim 1, wherein the first layer comprises niobium nitride (NbN) or niobium carbide (NbC).

12. A processing method, comprising treating a first layer formed in a device feature formed on a surface of a substrate, wherein treating the first layer comprises:
establishing a dual radio frequency (RF) capacitively coupled plasma (CCP) in a plasma processing chamber by:
delivering a plurality of process gases to a processing region of the plasma processing chamber, wherein the plurality of process gases comprises a first gas and a second gas;
delivering a first RF power at a first RF frequency from a first RF generator to a first electrode of the plasma processing chamber; and
delivering a second RF power at a second RF frequency from a second RF generator to the first electrode of the plasma processing chamber, wherein:
the delivering the first RF power and the second RF power comprises pulsing the first RF power and the second RF power at a duty cycle and a pulsing frequency;
the first RF frequency is greater than the second RF frequency; and
the dual RF frequency capacitively coupled plasma (CCP) is formed between the first electrode and the substrate that is disposed on a substrate supporting surface of a substrate support.

13. The method of claim 12, wherein the device feature comprises a carbon containing layer.

14. The method of claim 13, wherein the first gas comprises hydrogen (H₂) and the second gas comprises argon (Ar).

15. The method of claim 14, wherein:
the pulsing frequency is between 10 kilohertz (kHz) and 100 KHz; and
the first RF frequency is greater than 13.56 megahertz (MHz) and the second RF frequency is less than or equal to 13.56 MHz.

16. The method of claim 15, wherein the first gas and the second gas are provided at a second gas to first gas ratio that is between about 0.0001 and about 0.1.

17. The method of claim 13, wherein the device feature further comprises one or more metal layers comprising titanium (Ti), tantalum (Ta), molybdenum (Mo), tungsten (W), ruthenium (Ru), zirconium (Zr), niobium (Nb), or combinations thereof.

18. The method of claim 16, wherein the device feature comprises one or more metal layers comprising Ti, Ta, Mo, W, Ru, Zr, or Nb, or combinations thereof.

19. The method of claim 18, wherein the first gas comprises H₂ and the second gas comprises Ar.

20. The method of claim 19, wherein:
the pulsing frequency is between 10 kHz and 100 KHz; and
the first RF frequency is greater than 13.56 MHz and the second RF frequency is less than or equal to 13.56 MHz.
